(19) United States
(12) Patent Application Publication
(10) Pub. No.: US 2004/0135189 A1
(43) Pub. Date: Jul. 15, 2004

(54) Semiconductor device

(76) Inventor: Masahiro Kiyotoshi, Sagamihara-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/712,377

(22) Filed: Nov. 14, 2003

(30) Foreign Application Priority Data
Nov. 15, 2002 (JP) 2002-332093

(51) Int. Cl. H01L 27/108

(52) U.S. Cl. 257/306

(57) ABSTRACT

A semiconductor device is disclosed, which comprises a semiconductor substrate, a multilayer metal wiring layer, a capacitor comprising first and second elements, each element including a lower metal electrode, a dielectric film, and an upper metal electrode stacked formed on the multilayer metal wiring layer, and first and second wiring layers of an upper layer formed on an insulation film which covers the capacitor, wherein the upper metal electrodes have the same size and shape, the upper metal electrode of each element is provided within an area in which the lower metal electrode and the dielectric film of the each element are stacked, and the lower metal electrode of the first element and the upper metal electrode of the second element are connected to each other, and the upper metal electrode of the first element and the lower metal electrode of the second element are connected to each other.

### CROSS-REFERENCE TO RELATED APPLICATIONS

This application is based upon and claims the benefit of priority from the prior Japanese Patent Application No. 2002-332093, filed Nov. 15, 2002, the entire contents of which are incorporated herein by reference.

### BACKGROUND OF THE INVENTION

1. Field of the Invention

The present invention relates to a semiconductor device including an MIM (Metal-Insulator-Metal) capacitor used for RF (Radio Frequency) communication and the like.

2. Description of the Related Art

As the communication techniques develop, it has become rare to use a personal computer (PC) or a personal digital assistant (PDA) in a stand-alone form, and it has become normal to connect the personal computer (PC) or the personal digital assistant (PDA) to a network. It is predicted that electric household appliances, such as a refrigerator and an air conditioner, are also connected to a network in the future. In the case where a network is formed by using a large number of such devices, networking individual devices with a LAN cable, which has been conducted in offices or the like heretofore, is not suitable to the ordinary home, and it is considered that wireless connection using the radio frequency will become the mainstream. Therefore, it is also considered that the RF communication function will be added to most LSI chips in the future. Heretofore, each of LSIs used in such application is formed of a plurality of chips including an RF analog device (such as SiGe-BiCMOS) and a CMOS logic device according to the application. Since importance is attached to size reduction in the personal digital assistants or the like, it is demanded to implement desired circuit performance while reducing the area occupied by a printed circuit board. Accordingly, further size reduction of RF-hybrid LSIs is demanded.

Furthermore, in order to make it possible for device manufacturers to use RF communication more easily, it is demanded to incorporate the RF analog device and the CMOS logic device into a single chip so that even a user who has no experience of designing an RF circuit may use the RF communication function.

On the other hand, for incorporating the RF analog device and the CMOS logic device in a single chip, it is necessary to unify fabrication processes of the both devices. The RF analog device includes resistors, inductances, and capacitors. The CMOS logic device includes MOS transistors. For implementing the hybrid LSI, therefore, it becomes necessary to unify the manufacturing process of the RF analog device to the CMOS logic process serving as the base, and develop a new RF-CMOS process.

When unifying both processes, the structure and fabrication process of the capacitors first pose a problem. The reason will now be described. Capacitors having a plurality of purposes are needed in order to mount the RF analog circuit mixedly. Demanded specifications differ according to respective purposes. However, the demanded specifications must be satisfied with capacitors having a single specification (such as a capacity density and a leakage current characteristic per unit area). That is the reason. For example, only a voltage of several tens microvolts is applied to a capacitor used in a noise filter in an RF reception unit. On the other hand, a voltage in the range of 2.5 to 3.6V is applied in an analog-digital converter (AD converter).

Therefore, capacitors mounted on the analog circuit are required to be capacitors having such a high insulating property as to be able to implement a low leakage current not only for use at a low voltage of several tens microvolts but also for use at a high voltage of 3V or so. Furthermore, requirements for voltage linearity of the quantity of electric charge stored across the capacitor as a function of the applied voltage also differ according to the purpose. Although linearity is not important in the above-described noise filter application, very good linearity is demanded in the AD converter. Schematically, the AD converter includes one capacitor 601 and two switching devices 602 and 603 as shown in FIG. 21. The switch devices 602 and 603 open and close at a switching cycle faster than the repetition period of the RF. When the switching device 602 is in the closed state, an RF signal input to an input terminal IN is written across the capacitor 601. Subsequently, the switching device 602 is opened, and the switching device 603 is closed. As a result, electric charge stored across the capacitor 601 is output to an output terminal OUT, and converted to a discrete numerical value in a computation circuit on the output side. By repeating the above-described process, the RF analog signal is subjected to time division and converted to a digital signal. One of important parameters that determine the conversion precision in the AD converter is linearity of the charge stored across the capacitor 601 as a function of the applied voltage.

In general, the quantity Q of charge stored across the capacitor is represented by a relation

Q=CV (1)

where C is the capacitance and V is the applied voltage. C is typically regarded as a constant. As a matter of fact, however, a weak perturbation term represented by equation (2) exists.

Q=CV=C₀(1+VCC1×V+VCC2×V²) (2)

In an ideal system, VCC1=VCC2=0. If VCC1=VCC2=0, then charge written into the capacitor 601 is converted to a digital signal without collapsing in waveform. If VCC1 or VCC2 is not 0, then the waveform is distorted especially in a large amplitude portion of the RF waveform, and subjected to analog-to-digital conversion. In particular, as compared with the VCC2, the VCC1 largely distorts the waveform even in the vicinity of 0V, and consequently largely affects the conversion performance of the AD converter. As capacitors built in the RF-hybrid circuit, therefore, nonlinearity caused by depletion in a silicon electrode poses a problem in MOS (Metal-Oxide-Semiconductor) capacitors and PIP (Poly-Si-Insulator-Poly-Si) capacitors, which have been widely used in conventional semiconductor devices. Therefore, the capacitors must be MIM capacitors in which electrode depletion cannot occur.

In other words, for implementing the RF-hybrid LSI, MIM capacitors having very high performance are demanded. On the other hand, there are always demands for making LSIs finer and reducing the chip area. In the case of the MIM capacitors, each of areas of individual capacitors is as large as several hundreds square microns, and consequently reduction of the capacitor area, i.e., increase of the capacitor capacitance per unit area becomes very important. For improving the capacitance density in such capacitors each having a large area, however, it is unreal to use a method of making an electrode into a three-dimensional form, utilizing side surface areas, increasing the effective capacitor surface area, and thereby increasing the capacitance per unit projection area, which has heretofore been used in DRAM capacitors. The reason is as follows. In a method of simply processing an electrode in a columnar shape and using the side surface areas in order to increase the side surface areas so as to correspond to a huge projection area, electrodes having a height of several tens microns become necessary, but it is difficult from the aspect of the fabrication technique. As a matter of fact, therefore, a complicated processing process for forming minute unevenness on the electrode surface is needed to increase the side surface area.

It is now under investigation to use a high dielectric constant material, such as alumina or tantalum oxide, instead of a silicon nitride film, which has heretofore been used as a dielectric in MIM capacitors, for such a purpose. Commercial production of MIM capacitors using a high dielectric constant material as a dielectric has been started in part.

By the way, if capacitors for the RF-hybrid circuit can be formed on multilayer wiring on a semiconductor substrate, then the process becomes simple, and in addition, the parasitic capacitance to ground becomes small because a distance from the semiconductor substrate can be assured. Because of such advantages, the capacitors for the RF-hybrid circuit are formed on the multilayer wiring of copper or aluminum. In compensation for it, however, the upper limit of the formation temperature of the MIM capacitors becomes 400° C. or so. Existence of a restriction in the upper limit of the process temperature makes it difficult to form a high dielectric constant film of good quality (in the case where a high dielectric constant material is investigated as the gate insulator film, a thermal process of at least 800° C. is typically used to remove defects in the film), and, in addition, means that defects formed in the high dielectric constant material by damage (process damage) caused by the process cannot be removed by thermal processing.

It is described in Jpn. Pat. Appln. KOKAI Publication No. 59-55047 (FIGS. 4 and 5 and page 5) and Jpn. Pat. Appln. KOKAI Publication No. 1-241858 (FIGS. 1 and 2 and page 2) to provide each of capacitors formed on the semiconductor substrate with a structure having reduced dependence on voltage.

As such process damage, plasma damage inflicted on a high dielectric constant material having a relative dielectric constant of, for example, at least 20 when forming an upper capacitor electrode by using the sputtering method, etching damage inflicted on the high dielectric constant film when processing the upper capacitor electrode, plasma damage inflicted when covering a capacitor with an interlayer insulation film formed by using plasma CVD (Chemical Vapour Deposition), and oxygen deficiency generation caused by a reducing atmosphere can be mentioned.

Furthermore, it is also considered as process damage that reaction with a metal film of the lower electrode (the most typical of which is reduction of the high dielectric constant material conducted by the lower electrode metal) occurs when forming a film of a high dielectric constant material. Especially, the damage caused by plasma process has close correlation with distribution of the plasma on the semiconductor substrate. In the case where a capacitor is formed on a substrate having 300 mmφ as in the current CMOS device, it cannot be anticipated that uniform damage is caused in the substrate surface, and the damage itself typically has distribution. Therefore, it is very difficult to form high dielectric constant MIM capacitors that are favorable in linearity with respect to the applied voltage over the whole surface of a large diameter substrate.

### BRIEF SUMMARY OF THE INVENTION

According to an aspect of the present invention, there is provided a semiconductor device comprising:

a semiconductor substrate on which a semiconductor element is formed;

a multilayer metal wiring layer having a plurality of layers stacked on the semiconductor substrate respectively via interlayer dielectric films;

a capacitor comprising first and second elements, each of the elements including a lower metal electrode, a dielectric film, and an upper metal electrode stacked formed on the multilayer metal wiring layer via an interlayer insulation film; and

first and second wiring layers of an upper layer formed on an insulation film, the insulation film being formed so as to cover the capacitor,

wherein the upper metal electrodes of the first and second elements have substantially the same size and shape,

the upper metal electrode of each of the elements is provided within an area in which the lower metal electrode and the dielectric film of the each element are stacked, and

the lower metal electrode of the first element and the upper metal electrode of the second element are electrically connected to each other, and the upper metal electrode of the first element and the lower metal electrode of the second element are electrically connected to each other.

According to another aspect of the present invention, there is provided a semiconductor device comprising:

a semiconductor substrate on which a semiconductor element is formed;

a multilayer metal wiring layer having a plurality of layers stacked on the semiconductor substrate respectively via interlayer dielectric films;

a dielectric film formed over the semiconductor substrate so as to cover the multilayer metal wiring layer;

first and second upper metal electrodes formed on the dielectric film, the first and second upper metal electrodes having substantially the same size and shape; and

first and second wiring layers of an upper layer formed on an insulation film, the insulation film being formed so as to cover the first and second upper metal electrodes and the dielectric film,

wherein a capacitor is formed of first and second elements,

the first element comprises the first upper metal electrode, the dielectric film, and a first lower metal electrode formed of a part of an uppermost wiring layer of the multilayer metal wiring layer,

the second element comprises the second upper metal electrode, the dielectric film, and a second lower metal electrode formed of another part of the uppermost wiring layer of the multilayer metal wiring layer,

the first upper metal electrode is provided within an area in which the first lower metal electrode and the dielectric film are stacked,

the second upper metal electrode is provided within an area in which the second lower metal electrode and the dielectric film are stacked, and

the first lower metal electrode of the first element and the second upper metal electrode of the second element are electrically connected to each other, and the first upper metal electrode of the first element and the second lower metal electrode of the second element are electrically connected to each other.

### BRIEF DESCRIPTION OF THE SEVERAL VIEWS OF THE DRAWING

FIG. 1 is a cross sectional view of a semiconductor device, for explaining a step of a manufacturing method according to a first embodiment of the present invention;

FIG. 2 is a cross sectional view of the semiconductor device, for explaining a step following the step of FIG. 1 of the manufacturing method according to the first embodiment of the present invention;

FIG. 3 is a plan view showing a pattern of upper capacitor electrodes formed on a semiconductor substrate of the semiconductor device shown in FIG. 2;

FIG. 4 is a cross sectional view of the semiconductor device, for explaining a step following the step of FIG. 2 of the manufacturing method according to the first embodiment of the present invention;

FIG. 5 is a plan view showing a pattern of the upper capacitor electrodes formed on the semiconductor substrate of the semiconductor device shown in FIG. 4;

FIG. 6 is a cross sectional view of the semiconductor device, for explaining a step following the step of FIG. 4 of the manufacturing method according to the first embodiment of the present invention;

FIG. 7 is a plan view showing a pattern of the upper capacitor electrodes formed on the semiconductor substrate of the semiconductor device shown in FIG. 6;

FIG. 8 is a schematic circuit diagram of a capacitor formed on the semiconductor substrate of the semiconductor device shown in FIG. 6;

FIG. 9 is a schematic structural diagram of a capacitor formed on a semiconductor substrate;

FIG. 10 is a cross sectional view of a semiconductor device according to a second embodiment of the present invention;

FIG. 11 is a plan view showing a pattern of upper capacitor electrodes formed on a semiconductor substrate of the semiconductor device according to the second embodiment shown in FIG. 10;

FIG. 12 is a schematic structural diagram of a capacitor formed on a semiconductor substrate;

FIG. 13 is a cross sectional view of a semiconductor device according to a third embodiment of the present invention;

FIG. 14 is a plan view showing a pattern of upper capacitor electrodes formed on a semiconductor substrate of the semiconductor device according to the third embodiment shown in FIG. 13;

FIG. 15 is a schematic structural diagram of a capacitor formed on a semiconductor substrate;

FIG. 16 is a cross sectional view of a semiconductor device according to a fourth embodiment of the present invention;

FIG. 17 is a plan view showing a pattern of upper capacitor electrodes formed on a semiconductor substrate of the semiconductor device according to the fourth embodiment shown in FIG. 16;

FIG. 18 is a schematic structural diagram of a capacitor formed on a semiconductor substrate;

FIG. 19 is a cross sectional view of a semiconductor device according to a fifth embodiment of the present invention;

FIG. 20 is a plan view showing a pattern of upper capacitor electrodes formed on a semiconductor substrate of the semiconductor device according to the fifth embodiment shown in FIG. 19; and

FIG. 21 is a schematic circuit diagram of an analog/digital converter, for explaining the principle of the operation.

### DETAILED DESCRIPTION OF THE INVENTION

Hereafter, embodiments of the present invention will be described with reference to the drawings.

First Embodiment

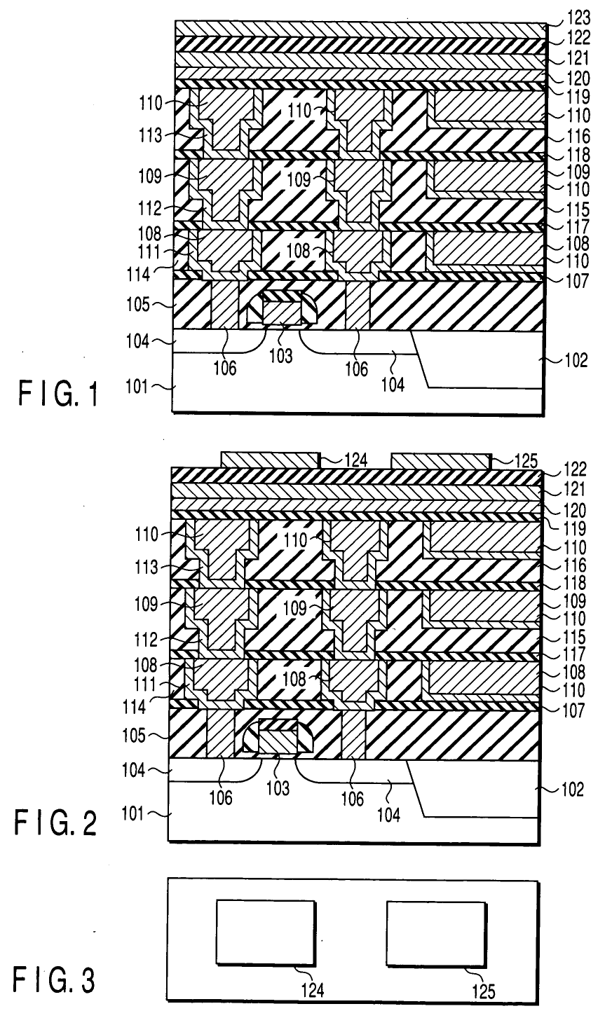

First, a first embodiment of the present invention will now be described with reference to FIGS. 1 to 8.

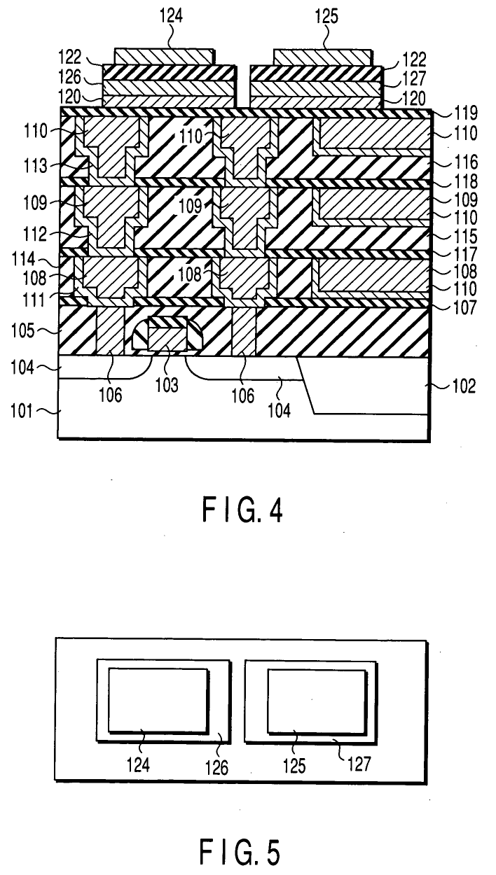

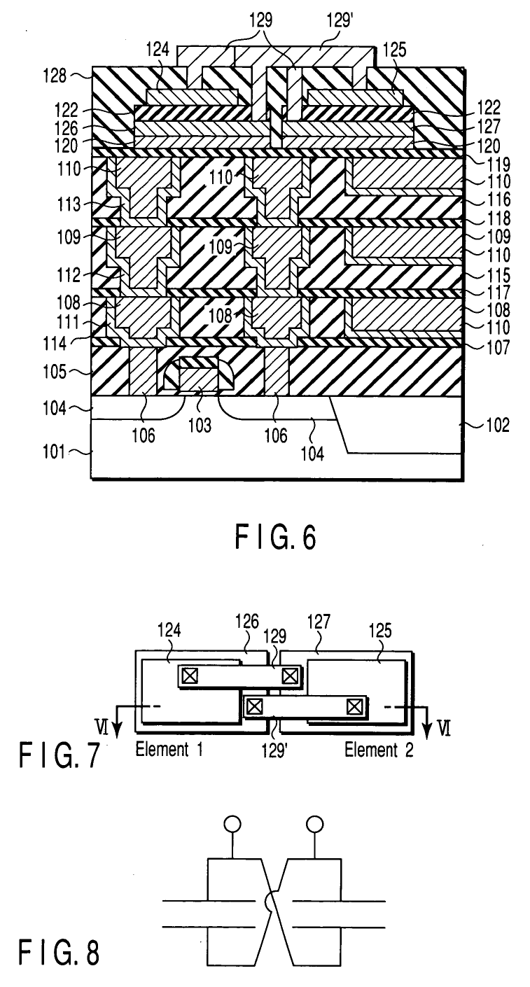

FIGS. 1, 2, 4 and 6 show cross sectionals of a semiconductor device in respective steps of a manufacturing method according to the first embodiment. FIG. 3 shows a pattern of upper electrodes of a capacitor formed on a semiconductor substrate of the semiconductor device of FIG. 2. FIG. 5 shows a pattern of the upper electrodes of the capacitor formed on the semiconductor substrate of the semiconductor device of FIG. 4. FIG. 7 shows a pattern of the upper electrodes of the capacitor formed on the semiconductor substrate of the semiconductor device of FIG. 6. FIG. 8 schematically shows a circuit diagram of the capacitor shown in FIG. 6.

As shown in FIG. 1, an element isolation region 102 is formed on a silicon semiconductor substrate 101 by using an existing technique. A gate electrode 103 and source/drain regions 104 are formed successively to form a MOS transistor as a semiconductor element, for example. Subsequently, an interlayer insulation film 105 is deposited on the semiconductor substrate 101 so as to cover the MOS transistor, and the interlayer insulation film 105 is planarized. Wiring on the semiconductor substrate is formed by Damascene method. Subsequently, via holes are formed in the interlayer insulation film 105, and metal films 106 serving as contact wiring are embedded in the via holes. A silicon nitride film 107 is formed on the interlayer insulation film 105 with the metal films 106 embedded therein. A first wiring layer 108 serving as a first layer, i.e., the lowermost layer, of multilayer wiring layer is formed on the silicon nitride film 107.

The first wiring layer 108 is formed of a metal film (a metal wiring layer) of Cu or the like. The side surface and bottom surface of the first wiring layer 108 are covered by a barrier layer 111 formed of TiN or the like. The metal wiring layer 108 are embedded in an interlayer insulation film (CVD-SiO₂) 114, which is formed on the silicon nitride film 107, so as to have the barrier layer (TiN) 111 between the metal wiring layer 108 and the interlayer insulation film 114. The barrier layer 111 is provided to prevent the metal material of the metal film 108 from being diffused into the interlayer insulation film 114. The metal wiring layer 108 is made of, for example copper, and is formed by using Damascene method. The first wiring layer 108 is electrically connected to the metal film 106 serving as contact wiring. A silicon nitride film 117 is formed on the interlayer insulation film 114 with the metal wiring layer 108 embedded therein. An interlayer insulation film 115 is deposited on the silicon nitride film 117, and planarized. A via hole to which the first wiring layer 108 is exposed and a wiring groove having an opening portion formed on a surface of the interlayer insulation film 115 are formed in the interlayer insulation film 115. By embedding a metal film in the via hole and the wiring groove, a second wiring layer 109 electrically connected to the first wiring layer 108 is formed. The second wiring layer 109 is formed of a metal film (metal wiring layer) of Cu or the like, and the side surface and bottom surface of the second wiring layer 109 are covered by a barrier layer 112 of TiN or the like.

A silicon nitride layer 118 is formed on the interlayer insulation film 115 with the second wiring layer 109 embedded therein. An interlayer insulation film 116 is deposited on the silicon nitride film 118, and planarized. A via hole to which the second wiring layer 109 is exposed and a wiring groove having an opening portion formed on a surface of the interlayer insulation film 116 are formed in the interlayer insulation film 116. By embedding a metal film in the via hole and the wiring groove, a third wiring layer 110 electrically connected to the second wiring layer 109 is formed. The third wiring layer 110 is formed of a metal film (metal wiring layer) of Cu or the like, and the side surface and bottom surface of the third wiring layer 110 are covered by a barrier layer 113 of TiN or the like. A silicon nitride film 119 is formed on the interlayer insulation film 116.

Subsequently, a titanium film 120, a titanium nitride film 121, a silicon nitride film 122, and a titanium nitride film 123 are successively deposited over the surface of the semiconductor substrate 101. The titanium nitride films 121 and 123 are formed by, for example, PVD (Physical Vapour Deposition). The silicon nitride film 122 is formed by, for example, the PVD or plasma CVD.

With reference to FIG. 2, the top of the titanium nitride film 123 is coated with a photoresist (not shown), and the photoresist is patterned. By using the patterned photoresist as a mask, the titanium nitride film 123 is etched to form upper electrodes 124 and 125 of a pair of capacitor elements (first and second elements) from the titanium nitride film 123. In other words, the upper electrodes 124 and 125 are comprised of the patterned titanium nitride film 123.

As shown in FIG. 3, the upper electrodes 124 and 125 formed by patterning the titanium nitride film 123 have substantially the same shape and the same size. In other words, the upper electrodes 124 and 125 have the same pattern and thus have substantially the same area.

Subsequently, with reference to FIG. 4, a photoresist (not shown) is coated over the surface of the substrate thus formed, and then patterned. By using the patterned photoresist as a mask, the silicon nitride film 122, the titanium nitride film 121 and the titanium film 120 are etched successively by means of RIE (Reactive Ion Etching) and ashing. Processing of respective layers forming the MIM capacitor is completed. A lower capacitor electrode 126 of the first element and a lower capacitor electrode 127 of the second element are thus formed. In other words, the lower electrode 126 and the lower electrode 127 are formed of the patterned titanium nitride film 121. A capacitor is formed of the first element and the second element formed at a distance from the first element.

The first element has a capacitor structure comprised of the lower capacitor electrode 126-the silicon nitride film (dielectric film) 122-the upper capacitor electrode 124. The second element has a capacitor structure comprised of the lower capacitor electrode 127-the silicon nitride film (dielectric film) 122-the upper capacitor electrode 125. Both the first and second elements are formed on the titanium film 120.

The lower capacitor electrodes and the dielectric films of respective elements are stacked, and they have the same pattern. Furthermore, as shown in FIG. 5, either upper capacitor electrode is provided within the range in which the dielectric film and the lower capacitor electrode are stacked. In other words, either upper capacitor electrode is provided within the pattern of the stack structure of the dielectric film and lower capacitor electrode.

As shown in FIG. 6, an interlayer insulation film 128 such as a silicon oxide film is formed so as to cover the capacitor. Subsequently, the entire surface of the semiconductor substrate is coated with a photoresist (not shown), and the photoresist is patterned. By using the patterned photoresist as a mask, the interlayer insulation film 128 is etched by means of lithography, RIE (Reactive Ion Etching), ashing to form contact holes, which communicate with the capacitor electrodes 124, 125, 126 and 127, in the interlayer insulation film 128. Subsequently, a metal film is formed on the whole surface of the interlayer insulation film 128. In addition, the entire surface of the metal film is coated with a photoresist (not shown), and the photoresist is patterned. By using the patterned photoresist as a mask, the metal film is etched by means of lithography, RIE (Reactive Ion Etching), ashing to form a patterned wiring layer of an upper layer. As shown in FIGS. 6 and 7, the patterned wiring layer comprises a wiring 129 and a wiring 129′ separated from each other, i.e., electrically independent of each other. The wiring 129 connects the upper capacitor electrode 124 of the first element to the lower capacitor electrode 127 of the second element, and the wiring 129′ connects the lower capacitor electrode 126 of the first element to the upper capacitor electrode 125 of the second element. In this way, the capacitor comprised of the first element and the second element is formed on the multilayer wiring layer of the semiconductor substrate.

In the semiconductor device formed in this embodiment, the process is further advanced such that an insulation film (not shown) that covers the wiring 129 and 129′ and the interlayer insulation film 128 and that is planarized in surface is formed. Further, connection pads electrically connected to the wiring layer of the upper layer are formed on the surface of the insulation film, and a protection film is formed, resulting in a product.

FIG. 6 is a cross sectional view taken along line VI-VI shown in FIG. 7. Nonetheless, not only the wiring 129′, but also wiring 129 are shown in FIG. 6. The wiring 129, which cannot be actually seen in FIG. 6, is shown to facilitate the understanding of the connection of the wiring 129 with the upper capacitor electrode 124 and the lower capacitor electrode 127.

A schematic circuit diagram of the capacitor of FIGS. 6 and 7 is shown in FIG. 8. This capacitor is symmetrical in the circuit diagram and VCC1 is substantially 0. The fabrication process for the MIM capacitor of this embodiment differs from that for the conventional MIM capacitor in only the lithography mask, and it does not bring about alteration or increase in the process.

In this embodiment, the silicon nitride film is used as the dielectric film and the titanium nitride film is used as an electrode film. However, this is not restrictive. For example, an alumina film, a tantalum oxide film, a hafnium oxide film, or a zirconium oxide film can be used as the capacitor dielectric film. A tungsten nitride film, a tantalum nitride film, a titanium nitride/AlCu/titanium nitride stacked film can also be used as the electrode film. For example, even if a stacked film structure including a different material layer, such as a tantalum oxide/alumina stacked film, is used as the dielectric film, the VCC1 can be made equal to substantially 0. Furthermore, even if a stacked film electrode structure using different material layers as the upper and lower electrodes, such as a stacked film electrode structure using a titanium nitride film as the upper electrode and a copper film as the lower electrode, is used, the VCC1 can be made equal to substantially 0.

The capacitor of the semiconductor device formed in this embodiment is used in, for example, an analog-digital converter (ADC). The analog-digital converter is supplied with an analog signal, and outputs a digital signal. In this embodiment, the multilayer wiring layer has three layers. However, there are no limits in the number of layers.

Second Embodiment

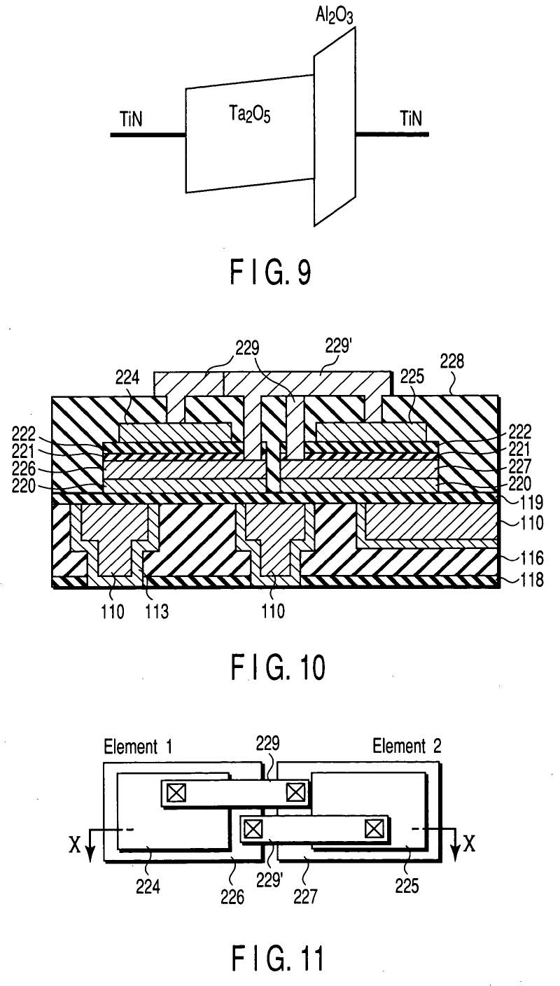

With reference to FIGS. 9 to 11, a second embodiment of the present invention will now be described.

FIG. 9 is a schematic structural diagram of a capacitor formed on a semiconductor substrate. FIG. 10 is a cross sectional view of a semiconductor device according to a second embodiment of the present invention. FIG. 11 is a plan view showing a pattern of upper capacitor electrodes formed on a semiconductor substrate of the semiconductor device according to the second embodiment shown in FIG. 10.

In FIG. 10, the semiconductor substrate is not shown, but an upper part of the multilayer wiring layer and a capacitor formed thereon are shown.

In FIG. 10, parts or portions corresponding to those in FIG. 1, 2, 4 or 6 of the first embodiment are denoted by corresponding numerals. Similarly, in FIG. 11, parts or portions corresponding to those in FIG. 7 of the first embodiment are denoted by corresponding numerals.

In this embodiment, the capacitance and the density can be increased by using Ta₂O₅ as the capacitor dielectric film, which is a high dielectric constant material having a relative dielectric constant of at least 20.

In general, an MIM capacitor formed of Ta₂O₅ and a TiN electrode has a large leakage current. Therefore, the MIM capacitor formed of Ta₂O₅ and a TiN electrode has a drawback that it brings about a signal distortion similar to VCC1 due to loss of the charge stored across the capacitor. Conventionally, therefore, the insulation property is enhanced by interposing an Al₂O₃ film between one of electrodes and the Ta₂O₅ film for the purpose of suppressing the leakage current. However, since the capacitor dielectric film structure has then an asymmetric stacked structure as shown in FIG. 9, the VCC1 is as large as approximately 1000 ppm.

Also in this embodiment, two capacitor elements having the same stacked structure and the same upper electrode shape are provided, and an upper electrode of each of the capacitor elements is electrically connected to a lower electrode of the other capacitor element to form one capacitor from these two capacitor elements. As a result, a lower leakage current can be implemented while making the VCC1 equal to substantially 0.

The process for forming a multilayer wiring layer on the semiconductor substrate serving as an underlying layer structure for the MIM capacitor is the same as that in the first embodiment, and consequently its description will be omitted.

In the same way as the first embodiment, the MIM capacitor is formed on the multilayer metal wiring layer. As shown in FIG. 10, a metal wiring layer 110, which is the top layer of the multilayer metal wiring layer, is embedded in an interlayer insulation film (CVDSiO₂) 116 via a barrier layer (TiN) 113. The metal wiring layer is formed by embedding a metal such as copper, by using the Damascene method. A silicon nitride layer 119 is formed on the metal wiring layer.

Subsequently, a titanium film 220 and then a titanium nitride film are formed over the surface of the semiconductor substrate. Subsequently, an Al₂O₃ film 221 is formed by using the ALD (Atomic Layer Deposition) method, and a Ta₂O₅ film 222 is formed by using the LPCVD method. Subsequently, a titanium nitride film serving as the upper electrode is formed by using the sputter method. The stacked films are processed to form a pair of capacitor elements comprised of first and second elements by using a method used in the first embodiment to process the titanium film 120, the titanium nitride film 121, the silicon nitride 122 and the titanium nitride film 123. The first element has a capacitor structure comprised of a lower capacitor electrode 226-the Al₂O₃ film (dielectric film) 221-the Ta₂O₅ film (dielectric film) 222-the upper capacitor electrode 224. The second element has a capacitor structure comprised of a lower capacitor electrode 227-the Al₂O₃ film (dielectric film) 221-the Ta₂O₅ film (dielectric film) 222-the upper capacitor electrode 225. Both the first and second elements are formed on the titanium film 220.

The lower capacitor electrodes and the dielectric films of the elements are stacked and have the same pattern. Furthermore, as shown in FIG. 11, either upper capacitor electrode is provided within the range in which the dielectric film and the lower capacitor electrode are stacked. In other words, either upper capacitor electrode is provided within the pattern of the stack structure of the dielectric film and lower capacitor electrode.

After the stacked films have been processed as described above, an interlayer insulation film 228 is formed. By using a photoresist pattern (not shown) as a mask, the interlayer insulation film 228 is etched by means of RIE to form contact holes, which communicate with the capacitor electrodes 224, 225, 226 and 227, in the interlayer insulation film 128. Subsequently, a metal film is formed over the surface of the interlayer insulation film 228. By using a photoresist pattern (not shown) as a mask, the metal film is etched by means of RIE to form a patterned wiring layer of an upper layer. The patterned wiring layer comprises a wiring 229 and a wiring 229′ separated from each other, i.e., electrically independent of each other. The wiring 229 connects the upper capacitor electrode 224 of the first element to the lower capacitor electrode 227 of the second element, and the wiring 2291 connects the lower capacitor electrode 226 of the first element to the upper capacitor electrode 225 of the second element. As a result, an MIM capacitor having a structure that is symmetrical in the circuit diagram is formed. The wiring 229 and 229′ serve as a metal wiring layer of an upper layer formed on the capacitor via the interlayer insulation film 228 (FIG. 10).

The process is further advanced such that an insulation film (not shown) that covers the wiring 229 and 229′ and the interlayer insulation film 228 and that is planarized in surface is formed. Thereafter, connection pads electrically connected to the wiring layer of the upper layer are formed on the surface of the insulation film, and a protection film is formed, resulting in a product.

FIG. 10 is a cross sectional view taken along line X-X shown in FIG. 11. Nonetheless, not only the wiring 229′, but also wiring 229 are shown in FIG. 10. The wiring 229, which cannot be actually seen in FIG. 10, is shown to facilitate the understanding of the connection of the wiring 229 with the upper capacitor electrode 224 and the lower capacitor electrode 227.

In this embodiment, the Al₂O₃ film is used as the dielectric film in order to suppress the leakage current. However, the dielectric film is not restricted to Al₂O₃ film, but it is also possible to use an insulation film such as SiO₂ or SiNx (x=1 to 1.33).

In this embodiment, the Ta₂O₅ film is used as a high dielectric constant material having a relative dielectric constant of at least 20. However, the high dielectric constant material is not restricted to this material, but a high dielectric constant material, such as Nb₂O₃, ZrO₂, HfO₂, La₂O₃ or Pr₂O₃, can be used.

Third Embodiment

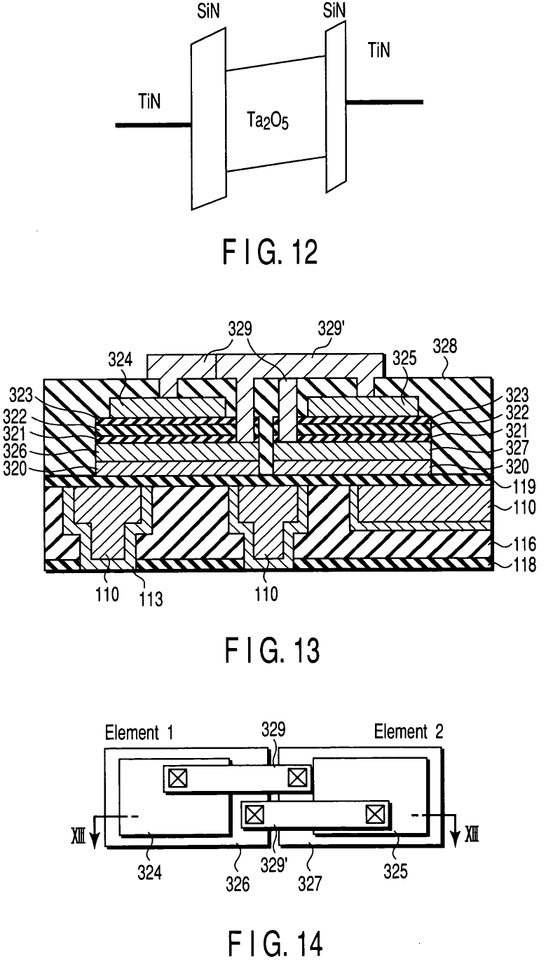

A third embodiment of the present invention will now be described with reference to FIGS. 12 to 14.

FIG. 12 is a schematic structural diagram of a capacitor formed on a semiconductor substrate. FIG. 13 is a cross sectional view of a semiconductor device according to a third embodiment of the present invention. FIG. 14 is a plan view showing a pattern of upper capacitor electrodes formed on a semiconductor substrate of the semiconductor device according to the third embodiment shown in FIG. 13. In FIG. 13, the semiconductor substrate is not shown, but an upper part of the multilayer wiring layer and a capacitor formed thereon are shown.

In FIG. 13, parts or portions corresponding to those in FIG. 1, 2, 4 or 6 of the first embodiment or FIG. 10 of the second embodiment are denoted by corresponding numerals. Similarly, in FIG. 14, parts or portions corresponding to those in FIG. 7 of the first embodiment or FIG. 11 of the second embodiment are denoted by corresponding numerals.

According to this embodiment, a VCC1 component caused by a difference in film thickness of two SiN films of a capacitor dielectric film of a structure comprising the two SiN films and a Ta₂O₅ film, which is interposed between the SiN films and is a high dielectric constant material having a relative dielectric constant of at least 20, is reduced.

In the structure of the second embodiment, an insulation film different from Ta₂O₅, is interposed on the lower electrode side in order to suppress the leakage current. In LSI application in which operation is guaranteed at a high temperature such as 125° C., it becomes necessary to interpose Ta₂O₅ between insulation films in order to suppress the leakage current. Since the insulation film provided to reduce the leakage current is typically lower in dielectric constant than Ta₂O₅, it is desirable to make its film thickness thin as far as possible for implementing a high capacitance density. The insulation film on the upper electrode side suffers plasma damage at the time of upper electrode sputtering more severely as compared with the insulation film on the lower electrode side. For obtaining a leakage current suppression effect equivalent to that for the insulation film on the lower electrode side, it is necessary to make the insulation film on the upper electrode side thick. For example, by inserting SiN having a thickness of 5 nm formed by PVD into an interface between the upper electrode and Ta₂O₅ and SiN having a thickness of 2 nm into an interface between Ta₂O₅ and the lower electrode, a low leakage current of 1.0×10⁻¹⁰ A/mm² or less can be implemented at 125° C. and ±3.6V. However, the capacitor dielectric film structure has an asymmetrical stacked structure as shown in FIG. 12. In other words, the SiN films on the upper and lower electrode sides have different thickness. Therefore, VCC1 is as large as approximately 600 ppm.

Like the first and second embodiments, also in this embodiment, two capacitor elements having the same stacked structure and the same upper electrode shape are provided, and an upper electrode of each of the capacitor elements is electrically connected to a lower electrode of the other capacitor element to form one capacitor from these two capacitor elements. As a result, a lower leakage current can be implemented while making the VCC1 equal to substantially 0.

The process for forming a multilayer wiring layer on the semiconductor substrate serving as an underlying layer structure for the MIM capacitor is the same as that in the first embodiment, and consequently its description will be omitted.

In the same way as the first and second embodiments, the MIM capacitor is formed on the multilayer metal wiring layer. As shown in FIG. 13, a metal wiring layer 110, which is the top layer of the multilayer metal wiring layer, is embedded in an interlayer insulation film (CVDSiO₂) 116 via a barrier layer (TiN) 113. The metal wiring layer is formed by embedding a metal such as copper, by using the Damascene method. A silicon nitride layer 119 is formed on the metal wiring layer.

Subsequently, a titanium film 320 and then a titanium nitride film are formed over the surface of the semiconductor substrate. Subsequently, an SiN film 321, a Ta₂O₅ film 322, an SiN film 323, and a TiN (titanium nitride) film serving as the upper electrode are successively formed by using the sputter method. The stacked films are processed to form a pair of capacitor elements comprised of first and second elements by using a method used in the first embodiment to process the titanium film 120, the titanium nitride film 121, the silicon nitride 122 and the titanium nitride film 123. The first element has a capacitor structure comprised of a lower capacitor electrode 326-the SiN film (dielectric film) 321-the Ta₂O₅ film (dielectric film) 322-the SiN film (dielectric film) 323-the upper capacitor electrode 324. The second element has a capacitor structure comprised of a lower capacitor electrode 327-the SiN film (dielectric film) 321-the Ta₂O₅ film (dielectric film) 322-the SiN film (dielectric film) 323-the upper capacitor electrode 325. Both the first and second elements are formed on the titanium film 320.

The lower capacitor electrodes and the dielectric films of the elements are stacked and have the same pattern. Furthermore, as shown in FIG. 14, either upper capacitor electrode is provided within the range in which the dielectric film and the lower capacitor electrode are stacked. In other words, either upper capacitor electrode is provided within the pattern of the stack structure of the dielectric film and lower capacitor electrode.

After the stacked films have been processed as described above, an interlayer insulation film 328 is formed. By using a photoresist pattern (not shown) as a mask, the interlayer insulation film 328 is etched by means of RIE to form contact holes, which communicate with the capacitor electrodes 324, 325, 326 and 327, in the interlayer insulation film 328. Subsequently, a metal film is formed over the surface of the interlayer insulation film 328. By using a photoresist pattern (not shown) as a mask, the metal film is etched by means of RIE to form a patterned wiring layer of an upper layer. The patterned wiring layer comprises a wiring 329 and a wiring 329′ separated from each other, i.e., electrically independent of each other. The wiring 329 connects the upper capacitor electrode 324 of the first element to the lower capacitor electrode 327 of the second element, and the wiring 329′ connects the lower capacitor electrode 326 of the first element to the upper capacitor electrode 325 of the second element. As a result, an MIM capacitor having a structure that is symmetrical in the circuit diagram is formed. The wiring 329 and 329′ serve as a metal wiring layer of an upper layer formed on the capacitor via the interlayer insulation film 328 (FIG. 13).

The process is further advanced such that an insulation film (not shown) that covers the wiring 329 and 329′ and the interlayer insulation film 328 and that is planarized in surface is formed. Thereafter, connection pads electrically connected to the wiring layer of the upper layer are formed on the surface of the insulation film, and a protection film is formed, resulting in a product.

FIG. 13 is a cross sectional view taken along line XIII-XIII shown in FIG. 14. Nonetheless, not only the wiring 329′, but also wiring 329 are shown in FIG. 13. The wiring 329, which cannot be actually seen in FIG. 13, is shown to facilitate the understanding of the connection of the wiring 329 with the upper capacitor electrode 324 and the lower capacitor electrode 327.

Although the SiN film is used in this embodiment in order to suppress the leakage current, it is also possible to use an insulation film, such as SiO₂, ZrO₂, HfO₂, La₂O₃ or Pr₂O₃. Furthermore, although the sputtering method is used in this embodiment in order to form the SiN and Ta₂O₅ films, it is also possible to form the SiN and Ta₂O₅ films by using the CVD method or the coating method.

Fourth Embodiment

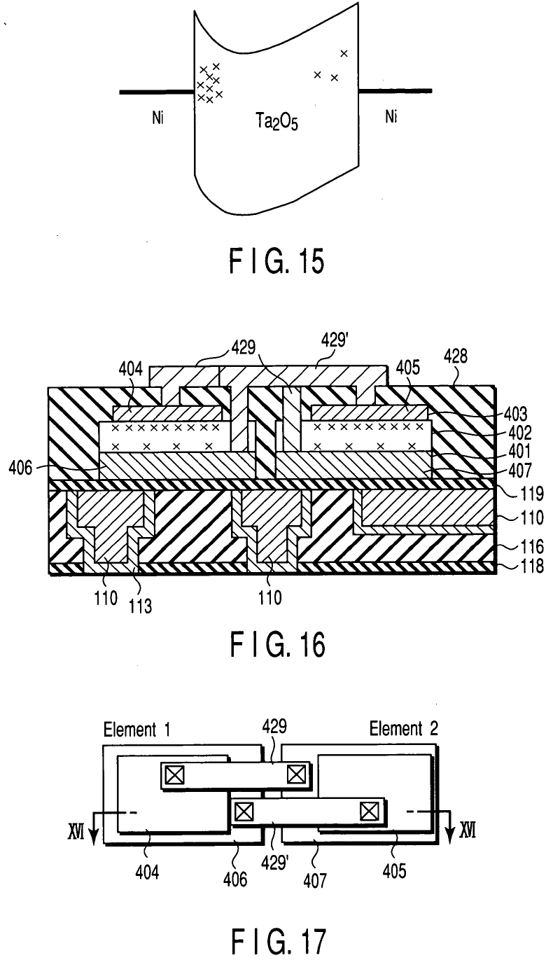

A fourth embodiment of the present invention will now be described with reference to FIGS. 15 to 17.

FIG. 15 is a schematic structural diagram of a capacitor formed on a semiconductor substrate. FIG. 16 is a cross sectional view of a semiconductor device according to a fourth embodiment of the present invention. FIG. 17 is a plan view showing a pattern of upper capacitor electrodes formed on a semiconductor substrate of the semiconductor device according to the fourth embodiment shown in FIG. 16. In FIG. 16, the semiconductor substrate is not shown, but an upper part of the multilayer wiring layer and a capacitor formed thereon are shown.

In FIG. 16, parts or portions corresponding to those in FIG. 1, 2, 4 or 6 of the first embodiment, FIG. 10 of the second embodiment, or FIG. 13 of the third embodiment are denoted by corresponding numerals. Similarly, in FIG. 17, parts or portions corresponding to those in FIG. 7 of the first embodiment, FIG. 11 of the second embodiment, or FIG. 14 of the third embodiment are denoted by corresponding numerals.

According to this embodiment, Ni electrodes are used as the upper and lower electrodes of the MIM capacitor using Ta₂O₅, which is a high dielectric constant material having a relative dielectric constant of at least 20.

Since an interface between the Ni electrode and Ta₂O₅ is thermally stable, the barrier layer of SiN or the like as shown in the second and third embodiments becomes unnecessary, and it is possible to obtain a very high capacitance density while easily obtaining a low leakage current. The limit of an increased capacitance density is approximately 7 fF/μm² in the case of Ta₂O₅ having a thickness of 30 nm, and it is approximately 4 fF/μm² in a structure in which a low dielectric constant material is inserted in an interface between Ta₂O₅ and the electrode. However, the value of VCC1 is as large as 800 ppm. The reason is that defects (i.e., oxygen deficiency) caused by plasma damage occur in the Ta₂O₅ film especially when forming Ni of the upper electrode by using sputtering. In FIGS. 15 and 16, oxygen deficiency is schematically denoted by “X.” Since the oxygen deficiency acts as a donor having valence equivalent to two, the energy band is curved and consequently the band structure in the vertical direction in each of the elements becomes asymmetric, resulting in increased VCC1.

Like the first, second and third embodiments, also in this embodiment, two capacitor elements having the same stacked structure and the same upper electrode shape are provided, and an upper electrode of each of the two capacitor elements is electrically connected to a lower electrode of the other capacitor element to form one capacitor from these capacitor elements. As a result, a lower leakage current can be implemented while making the VCC1 equal to substantially 0.

The process for forming a multilayer wiring layer on the semiconductor substrate serving as an underlying layer structure for the MIM capacitor is the same as that in the first embodiment, and consequently its description will be omitted.

In the same way as the first, second and third embodiments, the MIM capacitor is formed on the multilayer metal wiring layer.

As shown in FIG. 16, a metal wiring layer 110, which is the top layer of the multilayer metal wiring layer, is embedded in an interlayer insulation film (CVDSiO₂) 116 via a barrier layer (TiN) 113. The metal wiring layer is formed by embedding a metal such as copper, by using the Damascene method. A silicon nitride layer 119 is formed on the metal wiring layer.

Subsequently, a nickel (Ni) film 401, a Ta₂O₅ film 402, and a nickel (Ni) film 403 serving as the lower electrode are successively formed over the surface of the silicon nitride layer 119 on the semiconductor substrate by using the sputter method. The stacked films are processed to form a pair of capacitor elements comprised of first and second elements by using a method used in the first embodiment to process the titanium film 120, the titanium nitride film 121, the silicon nitride 122 and the titanium nitride film 123. The first element has a capacitor structure comprised of a lower capacitor electrode 406-the Ta₂O₅ film (dielectric film) 402-the upper capacitor electrode 404. The second element has a capacitor structure comprised of a lower capacitor electrode 407-the Ta₂O₅ film (dielectric film) 402-the upper capacitor electrode 405. The lower capacitor electrodes and the dielectric films of the elements are stacked and have the same pattern. Furthermore, as shown in FIG. 17, either upper capacitor electrode is provided within the range in which the dielectric film and the lower capacitor electrode are stacked. In other words, either upper capacitor electrode is provided within the pattern of the stack structure of the dielectric film and lower capacitor electrode.

After the stacked films have been processed as described above, an interlayer insulation film 428 is formed. By using a photoresist pattern (not shown) as a mask, the interlayer insulation film 428 is etched by means of RIE to form contact holes, which communicate with the capacitor electrodes 404, 405, 406 and 407, in the interlayer insulation film 428. Subsequently, a metal film is formed over the surface of the interlayer insulation film 428. By using a photoresist pattern (not shown) as a mask, the metal film is etched by means of RIE to form a patterned wiring layer of an upper layer. The patterned wiring layer comprises a wiring 429 and a wiring 429′ separated from each other, i.e., electrically independent of each other. The wiring 429 connects the upper capacitor electrode 404 of the first element to the lower capacitor electrode 407 of the second element, and the wiring 429′ connects the lower capacitor electrode 406 of the first element to the upper capacitor electrode 405 of the second element. As a result, an MIM capacitor having a structure that is symmetrical in the energy band is formed. The wiring 429 and 429′ serve as a metal wiring layer of an upper layer formed on the capacitor via the interlayer insulation film 428 (FIG. 16).

The process is further advanced such that an insulation film (not shown) that covers the wiring 429 and 429′ and the interlayer insulation film 428 and that is planarized in surface is formed. Thereafter, connection pads electrically connected to the wiring layer of the upper layer are formed on the surface of the insulation film, and a protection film is formed, resulting in a product.

FIG. 16 is a cross sectional view taken along line XVI-XVI shown in FIG. 17. Nonetheless, not only the wiring 429′, but also wiring 429 are shown in FIG. 16. The wiring 429, which cannot be actually seen in FIG. 16, is shown to facilitate the understanding of the connection of the wiring 429 with the upper capacitor electrode 404 and the lower capacitor electrode 407.

Fifth Embodiment

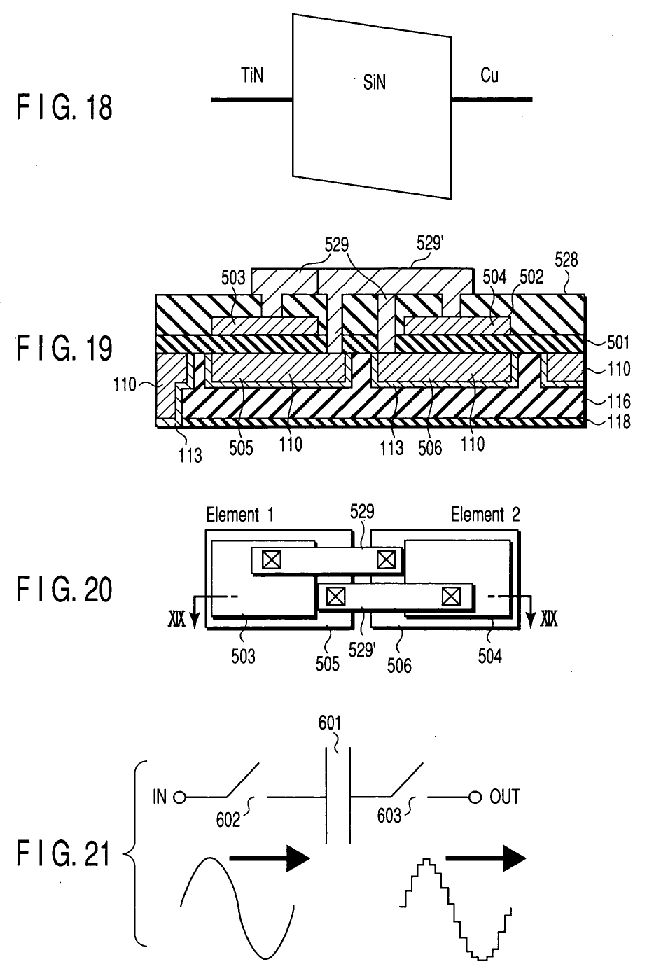

A fifth embodiment of the present invention will now be described with reference to FIGS. 18 to 20.

FIG. 18 is a schematic structural diagram of a capacitor formed on a semiconductor substrate. FIG. 19 is a cross sectional view of a semiconductor device according to a fifth embodiment of the present invention. FIG. 20 is a plan view showing a pattern of upper capacitor electrodes formed on a semiconductor substrate of the semiconductor device according to the fifth embodiment shown in FIG. 19.

In FIG. 19, the semiconductor substrate is not shown, but an upper part of the multilayer wiring layer and a capacitor formed thereon are shown.

In FIG. 19, parts or portions corresponding to those in FIG. 1, 2, 4 or 6 of the first embodiment, FIG. 10 of the second embodiment, FIG. 13 of the third embodiment, or FIG. 16 of the fourth embodiment are denoted by corresponding numerals. Similarly, in FIG. 20, parts or portions corresponding to those in FIG. 7 of the first embodiment, FIG. 11 of the second embodiment, FIG. 14 of the third embodiment, or FIG. 17 of the fourth embodiment are denoted by corresponding numerals.

According to this embodiment, the asymmetry caused by using different kinds of material for the upper and lower electrodes is eliminated. A part of the metal wiring layer 110, which is the top layer of the multilayer metal wiring layer, is used as a lower electrode 505, 506 of the MIM capacitor in this embodiment.

As the resistance of the electrode of the MIM capacitors becomes low, the circuit characteristic (Q value) is improved. Therefore, it is desirable that the resistance of the electrode is low. Copper (Cu) used in multilayer wiring of the semiconductor device (LSI) as a low-resistance electrode is a promising material. In addition, there is also an advantage in fabrication that the lower electrodes of the MIM capacitors can be formed simultaneously when forming the wiring layer. However, processing Cu is conducted typically by using the Damascene method, it is difficult to use the Damascene method for the upper electrodes of the MIM capacitors. Because processing on the upper electrodes of the MIM capacitors is conducted typically by using the RIE technique. If TiN, which has heretofore been used, is used in the upper electrodes, then the energy band becomes asymmetrical as shown in FIG. 18, because the Schottky barrier height between SiN and TiN is different from that between SiN and Cu, and the value of VCC1 is as large as approximately 180 ppm.

Like the first, second, third and fourth embodiments, also in this embodiment, two capacitor elements having the same stacked structure and the same upper electrode shape are provided, and an upper electrode of each of the two capacitor elements is electrically connected to a lower electrode of the other capacitor element to form one capacitor from these two capacitor elements. As a result, a lower leakage current can be implemented while making the VCC1 equal to substantially 0.

The process for forming a multilayer wiring layer on the semiconductor substrate serving as an underlying layer structure for the MIM capacitor is the same as that in the first embodiment, and consequently its description will be omitted.

A part of the metal wiring layer 110, which is the top layer of the multilayer metal wiring layer, is used as a lower electrode 505, 506 of the MIM capacitor in this embodiment.

As shown in FIG. 19, a metal wiring layer 110, which is the top layer of the multilayer metal wiring layer, is embedded in an interlayer insulation film (CVDSiO₂) 116 via a barrier layer (TiN) 113. The metal wiring layer 110 is formed by embedding a metal such as copper, by using the Damascene method.

Subsequently, a silicon nitride film 501 and a titanium nitride film 502 are successively formed over the surface of the metal wiring layer 110 of the top layer of the multilayer metal wiring layer and the surface of the interlayer insulation film 116 by using the sputter method. A part of the metal wiring layer 110 becomes a lower capacitor electrode, and the titanium nitride film 502 becomes an upper capacitor electrode. Then, the titanium nitride film 502 is processed to form upper capacitor electrodes 503 and 504 by using a method used in the first embodiment, and the silicon nitride film 501 is processed to form capacitor dielectric films 501, 501, so that a pair of capacitor elements comprised of first and second elements are used, in which a part of the metal wiring layer 110 constitutes upper capacitor electrodes 505 and 506. The first element has a capacitor structure comprised of a lower capacitor electrode 505 (a part of the metal wiring layer 110)-the silicon nitride film (dielectric film) 501-the upper capacitor electrode 503. The second element has a capacitor structure comprised of a lower capacitor electrode 506-the silicon nitride film (dielectric film) 501-the upper capacitor electrode 504.

The lower capacitor electrodes and the dielectric films of the elements are stacked and have the same pattern. Furthermore, as shown in FIG. 20, either upper capacitor electrode is provided within the range in which the dielectric film and the lower capacitor electrode are stacked. In other words, either upper capacitor electrode is provided within the pattern of the stack structure of the dielectric film and lower capacitor electrode.

After the stacked films 501, 502 have been processed as described above, an interlayer insulation film 528 is formed. By using a photoresist pattern (not shown) as a mask, the interlayer insulation film 528 is etched by means of RIE to form contact holes, which communicate with the capacitor electrodes 503, 504, 505 and 506, in the interlayer insulation film 528. Subsequently, a metal film is formed over the surface of the interlayer insulation film 528. By using a photoresist pattern (not shown) as a mask, the metal film is etched by means of RIE to form a patterned wiring layer of an upper layer. The patterned wiring layer comprises a wiring 529 and a wiring 529′ separated from each other, i.e., electrically independent of each other. The wiring 529 connects the upper capacitor electrode 503 of the first element to the lower capacitor electrode 506 of the second element, and the wiring 529′ connects the lower capacitor electrode 505 of the first element to the upper capacitor electrode 504 of the second element. As a result, an MIM capacitor having a structure that is symmetrical in the energy band is formed. The wiring 529 and 529′ serve as a metal wiring layer of an upper layer formed on the capacitor via the interlayer insulation film 528 (FIG. 19).

The process is further advanced such that an insulation film (not shown) that covers the wiring 529 and 529′ and the interlayer insulation film 528 and that is planarized in surface is formed. Thereafter, connection pads electrically connected to the wiring layer of the upper layer are formed on the surface of the insulation film, and a protection film is formed, resulting in a product.

FIG. 19 is a cross sectional view taken along line XIX-XIX shown in FIG. 20. Nonetheless, not only the wiring 529′, but also wiring 529 are shown in FIG. 20. The wiring 529, which cannot be actually seen in FIG. 20, is shown to facilitate the understanding of the connection of the wiring 529 with the upper capacitor electrode 503 and the lower capacitor electrode 506.

The SiN film 501 is formed by the sputtering method. Because titanium nitride 502 serving as the upper electrodes can also be formed continuously by sputtering and it is effective in reducing the fabrication time. However, it is also possible to form the SiN film 501 by using the ordinary PECVD (plasma CVD) method instead of the sputtering.

Even in the case where defects caused in the capacitor insulation film by the process damage or the like do not exist symmetrically about the interface between the upper and lower electrodes, influence on VCC1 is canceled. This effect is extremely effective to MIM capacitors on the multilayer wiring layer, for which thermal processing for removing the process damage is substantially impossible.

As for the wiring for the MIM capacitors, the area of the MIM capacitors is extremely large, and consequently the wiring to the lower electrode is typically different in length from the wiring to the upper electrode, and the their inductances are largely different. Therefore, the circuit Q value tends to be worsened. However, it is possible to make inductances of wiring connected to the capacitor electrodes substantially equal to each other by connecting electrodes of the pair of capacitors to each other via the wiring layer of the upper layer. Therefore, it is effective to improvement of the circuit Q value.

The number of fabrication processes is not increased. The area of the MIM capacitors is originally as large as several hundreds micron order, whereas the current processing dimension of CMOS can be easily made equal to one micron order. Even if the structure of this embodiment is adopted, the influence on the area of the semiconductor device is hardly recognizable.

In each of the embodiments, a pair of capacitor elements on the semiconductor substrate have a symmetrical stacked structure, and consequently VCC1 can be made substantially equal to 0. As a result, an analog signal input to the capacitors is output as a digital signal free from distortion.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate on which a semiconductor element is formed;
a multilayer metal wiring layer having a plurality of layers stacked on the semiconductor substrate respectively via interlayer dielectric films;
a capacitor comprising first and second elements, each of the elements including a lower metal electrode, a dielectric film, and an upper metal electrode stacked formed on the multilayer metal wiring layer via an interlayer insulation film; and
first and second wiring layers of an upper layer formed on an insulation film, the insulation film being formed so as to cover the capacitor,
wherein the upper metal electrodes of the first and second elements have substantially the same area,
the upper metal electrode of each of the elements is provided within an area in which the lower metal electrode and the dielectric film of said each element are stacked, and
the lower metal electrode of the first element and the upper metal electrode of the second element are electrically connected to each other, and the upper metal electrode of the first element and the lower metal electrode of the second element are electrically connected to each other.

2. The semiconductor device according to claim 1, wherein the lower metal electrode of the first element and the upper metal electrode of the second element are electrically connected to each other by the first wiring layer, and the upper metal electrode of the first element and the lower metal electrode of the second element are electrically connected to each other by the second wiring layer.

3. The semiconductor device according to claim 1, wherein the dielectric film of each of the first and second elements of the capacitor comprises stacked films including a first film made of a high dielectric constant material and a second film made of a material having a low leakage current.

4. The semiconductor device according to claim 3, wherein the first film contains at least one of Ta₂O₅, Nb₂O₃, ZrO₂, HfO₂, La₂O₃ or Pr₂O₃, and the second film contains at least one of Al₂O₃, SiO₂ or SiN.

5. The semiconductor device according to claim 3, wherein the lower metal electrode of each of the first and second elements is made of TiN, and the upper metal electrode of each of the first and second elements is made of TiN.

6. The semiconductor device according to claim 1, wherein the dielectric film of each of the first and second elements of the capacitor comprises stacked films including a first film made of a high dielectric constant material and second and third films made of a material having a low leakage current, the second and third films interposing the first film therebetween.

7. The semiconductor device according to claim 3, wherein the first film contains at least one of Ta₂O₅, Nb₂O₃, ZrO₂, HfO₂, La₂O₃ or Pr₂O₃, and each of the second and third films contains at least one of Al₂O₃, SiO₂ or SiN.

8. The semiconductor device according to claim 6, wherein the lower metal electrode of each of the first and second elements is made of TiN, and the upper metal electrode of each of the first and second elements is made of TiN.

9. The semiconductor device according to claim 6, wherein the first film and the second film have different thickness.

10. The semiconductor device according to claim 1, wherein the dielectric film of each of the first and second elements comprises a high dielectric constant material having a relative dielectric constant of at least 20.

11. The semiconductor device according to claim 10, wherein the high dielectric constant material contains at least one of Ta₂O₅, Nb₂O₃, ZrO₂, HfO₂, La₂O₃ or Pr₂O₃.

12. A semiconductor device comprising:
a semiconductor substrate on which a semiconductor element is formed;
a multilayer metal wiring layer having a plurality of layers stacked on the semiconductor substrate respectively via interlayer dielectric films;
a dielectric film formed over the semiconductor substrate so as to cover the multilayer metal wiring layer;
first and second upper metal electrodes formed on the dielectric film, the first and second upper metal electrodes having substantially the same area; and
first and second wiring layers of an upper layer formed on an insulation film, the insulation film being formed so as to cover the first and second upper metal electrodes and the dielectric film,
wherein a capacitor is formed of first and second elements,
the first element comprises the first upper metal electrode, the dielectric film, and a first lower metal electrode formed of a part of an uppermost wiring layer of the multilayer metal wiring layer,
the second element comprises the second upper metal electrode, the dielectric film, and a second lower metal electrode formed of another part of the uppermost wiring layer of the multilayer metal wiring layer,
the first upper metal electrode is provided within an area in which the first lower metal electrode and the dielectric film are stacked,
the second upper metal electrode is provided within an area in which the second lower metal electrode and the dielectric film are stacked, and
the first lower metal electrode of the first element and the second upper metal electrode of the second element are electrically connected to each other, and the first upper metal electrode of the first element and the second lower metal electrode of the second element are electrically connected to each other.

13. The semiconductor device according to claim 12, wherein the first lower metal electrode of the first element and the second upper metal electrode of the second element are connected to each other by the first wiring layer of the upper layer, and the first upper metal electrode of the first element and the second lower metal electrode of the second element are connected to each other by the second wiring layer of the upper layer.

14. The semiconductor device according to claim 12, wherein the dielectric film of each of the first and second elements comprises a high dielectric constant material having a relative dielectric constant of at least 20.

15. The semiconductor device according to claim 14, wherein the high dielectric constant material contains at least one of Ta₂O₅, Nb₂O₃, ZrO₂, HfO₂, La₂O₃ or Pr₂O₃.

16. The semiconductor device according to claim 12, wherein the upper layer constituting the first and second metal layers is made of Cu.

17. The semiconductor device according to claim 1, wherein the multilayer metal wiring layer comprises at least two metal wiring layers.

18. The semiconductor device according to claim 1, wherein an analog circuit is formed in the semiconductor substrate, and the capacitor is included in the analog circuit.

19. The semiconductor device according to claim 18, wherein the analog circuit includes an analog/digital converter.
